(19) United States
(12) Patent Application Publication
(10) Pub. No.: US 2013/0069088 A1
(43) Pub. Date: Mar. 21, 2013

(54) LIGHT EMITTING DIODE WITH CONFORMAL SURFACE ELECTRICAL CONTACTS WITH GLASS ENCAPSULATION

(71) Applicant: The Regents of the University of California, Oakland, CA (US)

(72) Inventors: James S. Speck, Goleta, CA (US); Claude C. A. Weisbuch, Paris (FR); Nathan Pfaff, Goleta, CA (US); Leah Kuritzky, Goleta, CA (US); Christopher Lalau Keraly, Berkeley, CA (US)

(73) Assignee: THE REGENTS OF THE UNIVERSITY OF CALIFORNIA, Oakland, CA (US)

(21) Appl. No.: 13/623,472

(22) Filed: Sep. 20, 2012

Related U.S. Application Data
(60) Provisional application No. 61/536,837, filed on Sep. 20, 2011.

(51) Int. Cl. H01L 33/08; H01L 33/48; H01L 33/50

(52) U.S. Cl. 257/88; 257/98; 438/26; 257/E33.061; 257/E33.059

(57) ABSTRACT

An optoelectronic device (e.g., LED) comprising one or more conformal surface electrical contacts conforming to surfaces of the device; and a high refractive index glass partially or totally encapsulating the device and the conformal surface electrical contacts, wherein traditional wire bonds and/or bond pads are not used and the glass is a primary encapsulant for the device.

### CROSS-REFERENCE TO RELATED APPLICATIONS

This application claims the benefit under 35 U.S.C Section 119(e) of U.S. Provisional Patent Application Ser. No. 61/536,837 filed on Sep. 20, 2011, by James S. Speck, Claude Weisbuch, Nathan Pfaff, Leah Kuritzky, and Christopher Lalau Keraly, entitled “LIGHT EMITTING DIODE WITH CONFORMAL SURFACE ELECTRICAL CONTACTS WITH GLASS ENCAPSULATION,” attorney's docket number 30794.427-US-P1 (2012-121-1), which application is incorporated by reference herein.

This application is related to the following co-pending and commonly-assigned applications:

U.S. Utility patent application Ser. No. 12/275,136, filed on Nov. 20, 2008, by Steven P. DenBaars, Shuji Nakamura and Hisashi Masui, entitled “HIGH LIGHT EXTRACTION EFFICIENCY PACKAGE FOR A LIGHT EMITTING DIODE,” attorney's docket number 30794.290-US-I1 (2007-271), which application is a continuation-in-part of U.S. Utility patent application Ser. No. 11/940,872, filed on Nov. 15, 2007, by Steven P. DenBaars, Shuji Nakamura and Hisashi Masui, entitled “HIGH LIGHT EXTRACTION EFFICIENCY SPHERE LED,” attorney's docket number 30794.204-US-U1 (2007-271-2), which application claims the benefit under 35 U.S.C Section 119(e) of U.S. Provisional Patent Application Ser. No. 60/866,025, filed on Nov. 15, 2006, by Steven P. DenBaars, Shuji Nakamura and Hisashi Masui, entitled “HIGH LIGHT EXTRACTION EFFICIENCY SPHERE LED,” attorney's docket number 30794.204-US-P1 (2007-271-1);

which applications are incorporated by reference herein.

### BACKGROUND OF THE INVENTION

1. Field of the Invention

This invention relates to light emitting diode (LED) devices and compositions, and methods of fabrication thereof.

2. Description of the Related Art

(Note: This application references a number of different publications as indicated throughout the specification by one or more reference numbers within brackets, e.g., [x]. A list of these different publications ordered according to these reference numbers can be found below in the section entitled “References.” Each of these publications is incorporated by reference herein.)

FIG. 1 shows schematic side views of a) a traditional p side up horizontal LED 100 with topside contacts 102 and wire bonds (using wire 104 and bond 106), b) a flip chip LED 108 with backside solder bump bonds 110, and c) a vertical LED 112 with a backside contact 114 and topside wire bond 116.

Thus, current techniques for contacting LEDs use wire bonds to top side pads 102 in traditional horizontal devices 100, solders 110 for bump bonds for flip chip technology 108, or a combination of solder and topside wire bonds 116 in vertical devices 112, as shown in FIG. 1a, 1b and 1c respectively.

Each of the structures in FIG. 1 are then encapsulated with silicone or epoxy or polymer encapsulants with an index of refraction below 1.7. Encapsulation with materials having an index significantly less than the refractive index of the III-nitrides (2.5) leads to an extraction efficiency significantly less than unity.

To obtain a white light LED, one usually associates wavelength down-converting phosphors with a blue LED to generate new wavelengths in the yellow, green and red spectral regions. The encapsulant material may contain the phosphor material, for instance uniformly distributed in the encapsulant material, or the phosphor may be located in a thin layer on the LED chip, or in a thin layer somewhere remote from the LED, but within or on the surface of the encapsulant material. Epoxy encapsulants provide a rigid encapsulant material that protects the die and wire bonds from mechanical deformation, but as the LEDs are used, epoxies yellow with exposure to Ultraviolet (UV) radiation, becoming brittle and optically less transparent, thereby decreasing LED efficiency. Silicones have widely replaced epoxies because they maintain optical transparency over the lifetime of the device; however, silicones lack the rigidity of epoxies. As a result, silicones can be subject to damage via rough handling, and device failure can occur due to mechanical stress on the wire bonds.

In n-side up flip chip devices, the wire bonds have been removed and replaced by solder bump bonds on the lower surface of the device. Removal of the absorbing top contacts allows for full topside emission, and instead requires a highly reflective backside mirror. Reflectivity of the backside mirror must be >90% for good extraction within several bounces of the light, which proves difficult to achieve. N-side up devices are encapsulated via nearly identical techniques, and so face the same problems as traditional p-side up wire bonded LEDs. Additionally, the silicones and epoxies currently used are poor thermal conductors, and do not contribute significantly to device cooling by conducting the heat away from the chips, which is primarily done through the backside.

### SUMMARY OF THE INVENTION

The present invention discloses LEDs encapsulated by a high refractive index glass, either by a modular glass preform, or direct placement of soft, warm glass onto the LED followed by glass cooling. Standard electrical contacting of LEDs by wire bonding does not allow such fabrication due to the differences in coefficients of thermal expansion (CTEs) between glass, semiconductors, and metal wires.

Therefore, the present invention also describes a novel way of electrically contacting LEDs with conformal metal surface contacts before subsequently encapsulating the LEDs with a high refractive index glass, or glass preform with a high index intermediate medium. Side contacts may require an insulator to be deposited below the metal contact to prevent electrical shorting of the LED along the sidewall. The use of conformal contacts allows the removal of traditional wire bonds, preventing failures during high temperature encapsulation (especially if refractory metals are used for the contacts).

Currently LEDs are electrically contacted via gold wire bonds or backside bump solder bonds (in the case of flip chips). These wire bonds are suitable for currently used encapsulation media, usually silicone or epoxy based materials, which cure at relatively low temperatures (less than 200° C.). Both silicone and epoxy, however, present challenges for encapsulation of high efficiency, long lifetime LEDs. Epoxies develop a yellow color with exposure to UV light and so over the long lifetime of LEDs, the yellowing of the encapsulant decreases the optical transparency and the light output power decreases. Silicones are not rigid and can delaminate from LEDs, destroying the wire bonds under certain operating conditions. Both of the current encapsulants are also limited to fairly low refractive indices (n<1.7), compared to the LEDs internal refraction index (n>2.3 for InGaN alloys emitting in the visible spectrum). This index mismatch causes light extraction to be limited by total internal reflection. With a move to glass encapsulation, having indices of refraction greater than 1.7, it is possible to greatly enhance the light extraction efficiency, while allowing for additional functionality in the package, such as refractive index grading, phosphor incorporation for white light emission, resistance to optical degradation, and robust encapsulation to operate in any environment.

For moving to glass packaging, the electrical contacts must be able to withstand elevated temperatures, often above 200° C., for extended periods of time during packaging. By using the present invention, the gold wire bonds can be removed and replaced with high temperature tolerant refractory metals. Furthermore, the removal of the large bond pads, that are currently required, decreases the amount of light absorbed by the metals directly on the chip and within the final package. Current simulations indicate that metal contacts are responsible for 5-15% of the optical losses within the LED. By removing the large bond pads, the optical loss to the metal contacts can be significantly reduced or eliminated. Current backside solder bump bonds can be sufficient if using premolded glass encapsulants.

To overcome the limitations in the prior art described above, and to overcome other limitations that will become apparent upon reading and understanding the present specification, the present invention discloses an optoelectronic device, comprising one or more conformal surface electrical contacts conforming to surfaces of at least one light emitting device; and a high refractive index glass, having a refractive index of at least 1.7, partially or totally encapsulating the device and the conformal surface electrical contacts, wherein the glass is a primary encapsulant for the at least one light emitting device.

The glass can be an encapsulant dome or have a dome shape or dome cross-section.

The light emitting device can be a light emitting diode (LED), for example.

At least one of the conformal surface electrical contacts can extend from a top surface of the LED and along sidewalls of the LED to a header or carrier supporting the LED, wherein the header and the glass encapsulate the LED.

The conformal surface electrical can contacts include a flat surface contact on a backside of the LED.

The device can further comprise a high refractive index intermediate medium, wherein the high refractive index intermediate medium is on top of the conformal surface electrical contacts and between the LED and the glass, has a refractive index equal to or greater than the glass' refractive index, and less than or equal to the LED's refractive index, and index matches the glass.

The high refractive index intermediate medium can be a bonding agent that bonds the LED to the glass and a carrier or header for the LED, wherein the LED is totally encapsulated by the carrier and the glass.

The conformal metal surface electrical contacts can include side contacts with insulator between the side contacts and LED's sidewalls to prevent electrical shorting of the LED along the sidewalls.

The conformal metal surface electrical contacts can be comprised of refractory metals tolerant to temperatures greater than 200 degrees Celsius or greater than the glass' transition temperature.

The device can further comprise a phosphor layer between the glass and the LED.

A volume of non-glass and non-LED material between the LED and the glass can be minimized.

The glass can be in direct contact with the LED.

The glass can be molded or formed onto the LED to conform to the LED's shape.

The glass can replace silicone and epoxy as an encapsulant for the LED. For example, there may be no silicone and no epoxy encapsulant contacting the LED. In one or more embodiments, the glass may not be degraded over time (e.g., due to exposure to radiation or from operation of the LED), or the glass can be less degraded over time, as compared to a silicone or epoxy encapsulant. The light output power of the device, comprising the glass encapsulated LED of one or more embodiments of the present invention, can be less degraded over time, as compared to the device comprising the silicone or epoxy encapsulated LED.

The conformal surface electrical contacts can be used instead of traditional wire bonds and/or bond pads.

The device can comprise multiple LEDs with the one or more conformal surface electrical contacts conforming to surfaces of the LEDs and the high refractive index glass partially or totally encapsulating the LEDs and the conformal surface electrical contacts, wherein traditional wire bonds and/or bond pads are not used. Optical dams may separate the LEDs, and the LEDs may be shaped and positioned such that the LEDs act as a point source.

The multiple LEDs can be closely packed near the center of the encapsulant, so as to appear as much as possible as a single point source seen from the outer surface of the encapsulant dome shape, in order to optimize extraction. The LEDs can be closely packed near a center of the glass encapsulant dome.

The multiple LEDs can be in a single package, wherein different LEDs are coated with different phosphors, and the LEDs are independently electrically addressed so that varying color rendering is obtained by changing individual LED currents.

The present invention further discloses a method of fabricating the device.

The glass can be deposited on the LED at a temperature of more than 200 degrees or above the glass transition temperature, or at a temperature such that the glass is soft, flows, or moldable when the glass is deposited on the LED, thereby encapsulating the LED, and the conformal surface electrical contacts and the LED are not degraded by the deposition of the glass.

The LED can be deposited or mounted on a header prior to encapsulation.

The method can further comprise depositing a high refractive index intermediate medium onto the LED and the conformal surface electrical contacts; and depositing the glass onto the high refractive index intermediate medium to encapsulate the LED, wherein the high refractive index intermediate medium is between the LED and the glass and refractive index matches the glass.

The method can further comprise pre-forming or pre-molding the glass into a modular glass preform, prior to encapsulating the LED with the glass.

### BRIEF DESCRIPTION OF THE DRAWINGS

Referring now to the drawings in which like reference numbers represent corresponding parts throughout:

FIG. 1 illustrates schematic side views of a) a traditional p side up horizontal LED with topside contacts and wire bonds, b) a flip chip LED with backside solder bump bonds, and c) a vertical LED with a backside contact and topside wire bond.

FIG. 2 a) is a schematic side view of a conformal sidewall contacted LED, which, in one example, can comprise a traditional LED with conformal contacts, and FIG. 2 b) is a schematic of the conformal sidewall contacted LED from a top view, wherein the light gray depicts the LED chip, darker gray depicts the metal, and the dielectric is depicted in black.

FIG. 3 shows schematic side views of two example designs for an n-side up LED structure, comprising a) a flip chip structure (e.g., a traditional flip chip structure) in which the backside bump bonds are simply replaced by flat surface contacts and b) comprising a more complex structure where the p-contact covers the entire back surface with a photonic crystal between the active region and the p-contact, and where the n-contact has been replaced by a surface conformal contact insulated from the sidewall by a dielectric depicted in black.

FIG. 4 is a two dimensional planar representation of a light ray impinging upon an LED sidewall at an angle alpha (α), being totally internally reflected, and impinging upon a second sidewall at 90-alpha, at which point the light ray is extracted into the external medium.

FIG. 5 is a cross-sectional schematic illustrating details of a partially encapsulated n-side up LED, wherein the LED (depicted in light gray) is contacted by backside contacts resting on a dark gray diffuse scatterer, between the chip and the scatterer is a low refractive index high thermal conductivity medium, such as an epoxy, designed to reduce the critical angle at the lower interface, around the sidewalls and top surface is a high refractive index medium, such as a silicone loaded with titanium dioxide nanoparticles, followed by a phosphor layer (which also has a refractive index identical to that of the previous layer).

FIG. 6 is a schematic side view of an embodiment of the present invention in which the glass is in direct contact with the LED, wherein the LED (medium gray rectangle), the encapsulant (light gray semicircular area) and the header (dark grey rectangle) are shown.

FIG. 7 illustrates schematic side views of preformed glass encapsulants and possible attachments to LEDs on a header, wherein a) shows the preformed glass encapsulant without refractive index grading or additional functionality, b) shows an LED on a header that has been bonded to a preformed glass encapsulant (such as that in a)) with a non functionalized intermediate medium, and c) shows an LED on a header that has been bonded to a preformed glass encapsulant such as that in a) but with a functionalized intermediate medium.

FIG. 8 illustrates a cross sectional example of an optical “dam”.

FIG. 9 schematically illustrates top views of several possible arrangements of triangular LEDs for multi device packages.

FIG. 10 schematically illustrates side views of a) a glass encapsulated LED with an intermediate coating and remote phosphor attached to the carrier with a secondary material, and b) a glass encapsulated LED with an intermediate coating that also acts as the bonding layer and a phosphor layer.

FIG. 11 is a schematic side view of a glass structure surrounding both the LED, its glass encapsulant, and the phosphor structure.

FIG. 12 is a flowchart illustrating a method of fabricating an optoelectronic device.

FIG. 13 is a flowchart illustrating a method of fabricating a light source.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

There is a definitive need to increase the refractive index of the encapsulant material surrounding the semiconductor structure of LEDs, but high refractive index materials such as glasses require high temperature treatment. Additionally, their Coefficients of Thermal Expansion (CTE) are vastly different from those of LED materials. Currently, LEDs are electrically contacted via wire bonds, (or solder bump bonds in the case of flip chip technology) from positive and negative leads to the p-type and n-type pads respectively. Usually these electrical contacts are made via gold wires bonded to gold pads. The use of gold wire bonds and low temperature solders limits the temperature used for device encapsulation and operation. Additionally, wide temperature swings can stress, to the point of failure, the bond interface and the wires themselves. The large metalized areas required for solder bumps or wire bonding can cause large optical losses; 5 to 15% of the light emitted by the chip can be absorbed by these metalized areas. By replacing the current contact schemes with conformal surface contacts and high temperature solders or brazes, higher temperature encapsulants and operating temperatures can be used. This higher temperature tolerance allows the use of high refractive index glasses to be used as the encapsulant. In the case of a glass preform, an intermediate media may be placed around the LED in order to closely match the index of refraction of the encapsulant and the LED, in order to increase the light extraction efficiency. The second function is the use of an encapsulant that is mechanically robust and resistant to optical and thermal degradation over long LED lifetimes on the order of 50-70,000 hours. Long term reliability with high index of refraction is key to making long life high efficiency LEDs. The added functionality available with glass encapsulants, including the use of remote phosphors, graded index of refraction, and shaping of high quality optics, is important for increasing LED use in general and specialized lighting applications.

Technical Description

LED Fabrication

LEDs can be fabricated by standard lithographic and etch processes, with the sidewalls electrically insulated via the deposition of an optically transparent dielectric (if possible, with a high refractive index matched to that of the LED material).

Metal Contact Definition

Following the deposition of the dielectric insulation, metal contacts can be defined via standard photolithographic techniques and deposited via sputtering or evaporation.

LED Contacting.

Once LEDs are placed into their final packages, they can be contacted via a pre-deposited refractory metal pattern, and then contacted with a high temperature braze or high temperature curing paste.

The finished, electrically contacted LED 200 may have conformal sidewall electrical contacts 202 such as those shown in FIG. 2. FIG. 2 a) is a schematic side view of a conformal sidewall contacted LED 200, which, in one example, can comprise a traditional LED 200 with conformal contacts 202, and FIG. 2 b) is a schematic top view of the conformal sidewall contacted LED 200, wherein the light gray depicts the LED chip 200, darker gray depicts the metal 202, and dielectric 204 is depicted in black. In example, this can resemble a standard LED structure with top side contacts, often known as a p-side up LED.

The LED 200 can comprise an n-type layer/region 206, a p-type layer/region 208, and a light emitting active region/layer 210 between the p-type layer 208 and the n-type layer 206.

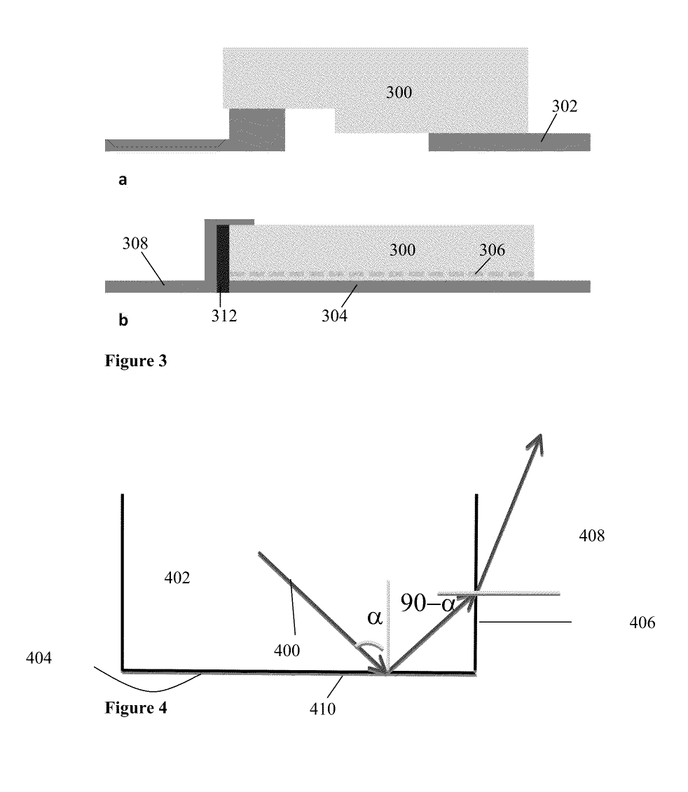

For n-side up structures (similar to current flip chip LEDs) the conformal sidewall contacts can replace backside solder bump bonds. Alternatively, the n-side up structures may not actually use the sidewalls, but just replace the backside bump bonds with surface contacts tolerant to higher temperatures. One of the problems facing flip chip technology is the creation of a highly reflective durable metal mirror on the p-side down chip. Although the substrate can be thinned or removed to reduce losses in the bulk, the mirror is extremely close to the active region and can result in large optical losses, similar to the losses due to the bond pads on a p-side up device. An identical problem can face an n-side up chip with conformal back or side contacts, but the situation can be mitigated by using a p-side photonic crystal to reduce the interaction of the optical modes with the mirror. Optical losses in the mirror can be avoided by using small backside contacts sufficient only to achieve uniform current spreading, and the use of a low refractive index material with high thermal conductivity to mount the chip, further discussed below. The n-side up structure can be similar to FIG. 3a, with a more complex n-side up vertical structure containing a photonic crystal and n-type top contact depicted in FIG. 3b.

FIG. 3 shows schematic side views of two examples of designs for an n-side up LED 300 structure, comprising a) a flip chip structure (e.g., traditional flip chip structure) in which the backside bump bonds are simply replaced by flat surface contacts 302 and b) a more complex structure where the p-contact 304 covers the entire back surface with a photonic crystal 306 between the active region and the p-contact, and where the n-contact has been replaced by a surface conformal contact 308 insulated from the sidewall 310 by a dielectric 312 depicted in black.

LED Mounting

Following LED chip fabrication, the devices need to be properly mounted before encapsulation.

Use of a Low Refractive Index, Optically Transparent, Thermally Conductive Material.

FIG. 4 is a two dimensional planar representation of a light ray 400 impinging upon an LED chip 402 sidewall 404 at an angle alpha (a), being totally internally reflected, and impinging upon a second sidewall 406 at 90-alpha, at which point the light ray 400 is extracted into the external medium 408.

By using a low refractive index material 410 on the backside sidewall 404, the light 400 impinging on the backside sidewall 404 of the chip 402 would likely experience total internal reflection (TIR), so that the light 400 would be directed upwards and would encounter the top surface with a higher index medium (where the light is more likely to fall within the critical angle). Backside sidewall 404 texturing randomizes the light impinging on the back surface, which will improve light extraction by minimizing repeated TIR. Note that the backside texturing does not need to be highly refined. Simple texturing via abrasion functions as well as PEC etching, or texturing formed in controlled manners, such as by RIE or ICP etching, to mimic PEC etching is sufficient. Another approach to achieve a high efficiency LED (e.g., high efficiency light extraction) is to create a slanted side in the LED, on any side which breaks the symmetry of the chip 402 and prevents repeated TIR.

The thermal conductivity of the material on the backside of the device is important to help with thermal management of the LED, as LEDs are known to decrease in efficiency and lifetime with increasing operation temperature. Finally, a diffuse scatterer on the backside sidewall 404 can help to scatter that light which does escape from the LED and ensure that it is not reabsorbed into the LED.

Coating With Index Matched Material

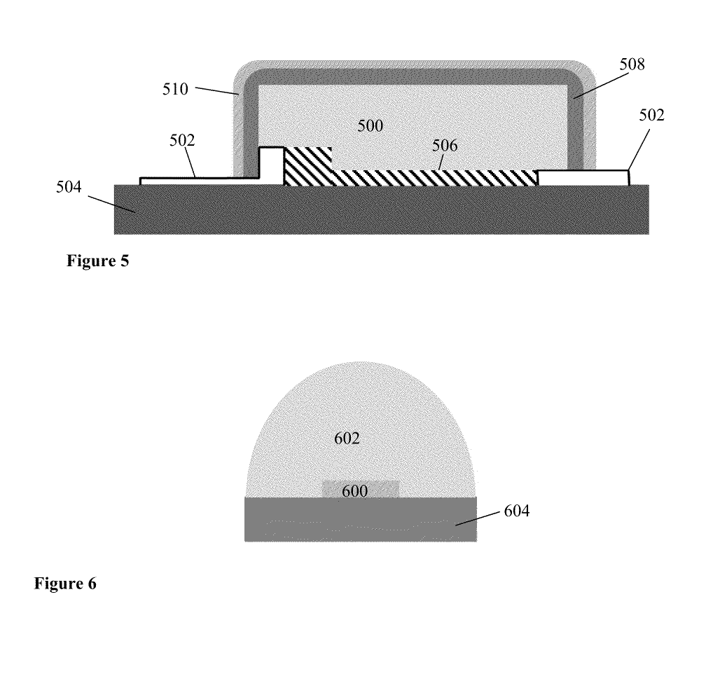

FIG. 5 illustrates details of a partially encapsulated n-side up LED, wherein the LED 500 is contacted by backside contacts 502 resting on a diffuse scatterer 504. Between the chip and the scatterer is a low refractive index high thermal conductivity medium 506, such as an epoxy, designed to reduce the critical angle at the lower interface. Around the sidewalls and top surface is a high refractive index medium 508, such as a silicone loaded with titanium dioxide nanoparticles, followed by a phosphor layer 510 (which also has a refractive index identical to that of the previous layer), and a glass cap (not shown).

The example described is for n-side up devices, however the same principles apply to both vertical and p-side up devices (just with different contacts, with no mirror, or backside texturing).

FIG. 5 shows that for n-side up devices, a low refractive index, optically transparent, thermally conductive material layer 506 can be used below the chip, but above a diffuse scattering surface for mounting the die.

The side and top surfaces of the LED structure can be coated with a material 508 that is index matched to the glass preform, as shown in FIG. 5. In the case of III-nitrides, the refractive index of this layer should be at least n=1.7. The reason the material does not have to index match the LED itself (n˜2.4) is easily seen in the planar description of light extraction illustrated in FIG. 4. FIG. 4 shows that for light to be extracted within one or zero bounces, the critical angle for total internal reflection must be greater than or equal to 45 degrees (so after only one reflection an initial TIR ray would be extracted).

The critical angle θ_{cr} is defined as:

$${θ}_{cr} = {sin}^{- 1} \frac{{n}_{2}}{{n}_{1}} , \qquad ( 1.1 )$$

and equation 1.1 can be rewritten as

$$sin {θ}_{cr} = \frac{{n}_{2}}{{n}_{1}} , \qquad ( 1.2 )$$

where n₂ is the refractive index of the encapsulant material (e.g., 408) and n₁ is the refractive index of the LED's 402 light emitting active region. For a critical angle θ_{c} of 45 degrees, sin)(45°)=0.707. For InGaN emitting at a wavelength of 450 nm, n₁=2.48. Substituting sin θ_{c}=0.707 and n₁=2.48 into equation 1.2:

$$0.707 = \frac{{n}_{2}}{2.48} , \qquad ( 1.3 )$$

and solving equation 1.3 for n₂ indicates that the encapsulant medium n₂ needs to have an index of at least 1.75. This is supported by the simulation data shown in Table 1 and Table 2.

TABLE 1
Light emitting efficiency (LEE) for a lossless simple point source within a
GaN block, and a GaN block with slanted sidewalls (angle of sidewall
does not change the result as long as it is slanted at least five degrees)
for varying refractive index encapsulants.

| | | Light emitting |
|---|---|---|
| | Light emitting | efficiency GaN |
| Refractive | efficiency GaN | Block, Slanted |
| Index | Block | Side |
| 1 | 0.253993 | 0.477813 |
| 1.1 | 0.306218 | 0.537122 |
| 1.2 | 0.362496 | 0.602388 |
| 1.3 | 0.433889 | 0.654351 |
| 1.4 | 0.512406 | 0.722971 |
| 1.5 | 0.595629 | 0.794202 |
| 1.6 | 0.692627 | 0.867280 |
| 1.7 | 0.800933 | 0.945602 |
| 1.8 | 0.900381 | 0.998140 |
| 1.9 | 0.968086 | 0.998893 |
| 2.0 | 0.993417 | 0.998391 |
| 2.1 | 0.994405 | |
| 2.2 | 0.995313 | |
| 2.3 | 0.997298 | |
| 2.4 | 0.999336 | |
| 2.5 | 1 | |

TABLE 2
Simulation results for the extraction efficiencies of LEDs with increasing
refractive index of the encapsulant and substrate.

| | | | Glass | Glass | Glass |
|---|---|---|---|---|---|
| | | Epoxy | (Index = | (Index = | (Index = |
| | Air | (Index = 1.5) | 1.8) | 2.0) | 2.2) |
| Roughened | 38.1% | 63.5% | 78.0% | 81.3% | 82.7% |
| GaN | | | | | |
| Patterned | 53.3% | 72.1% | 75.4% | 78.5% | 80.7% |
| Sapphire | | | | | |
| Smooth GaN | 19.8% | 48.4% | 72.9% | 81.2% | 82.8% |

Table 1 is for lossless structures, either with exact perpendicular sides or with slanted sidewalls. Notice that, in Table 1, for slanted sidewalls, Light Emitting Efficiency (LEE) approaches unity at n=1.8, while for a simple block structure, n=2 for an equivalent extraction.

Table 2 is calculated for real LED structures incorporating different sources of loss (contacts, transparent contact absorption, substrate absorption, bulk absorption).

Table 2 shows that by increasing the refractive index of the encapsulant from air, to epoxy, to higher refractive indices, n=1.8, n=2 and n=2.2, for a variety of native and non-native substrates, the extraction efficiencies can be greatly improved, with increases from 8 to 67%, for n=2 compared to n=1.5, depending on the substrate.

Notice that, in Table 2, the increase in refractive index of the encapsulant greatly enhances the extraction efficiency for all substrates. In Table 2, the largest enhancements occur for untextured homoepitaxial LEDs which have large volumes of high index material and do not use any of the current extraction enhancement techniques, such as surface roughening.

The index of the intermediate medium, be it a sol-gel glass, polymer or other medium, can be controlled either by composition and material choice, or by loading the material with higher index particles. In the case of polymer films, refractive indices are typically n˜1.5, so to achieve the desired n=1.8-2.2, the addition of nano-particles of a higher index material or materials can be used, often titanium dioxide [1,2,3,4]. In FIG. 5, this is layer 508 on top of the chip 500. Such high refractive index encapsulation with nano particles in a polymer matrix has been reported [5].

Use of Phosphors

A layer of remote distributed phosphor 510 can follow the high refractive index layer 508, as shown in FIG. 5. The phosphor layer 510 is used to create new colors, for instance to obtain a white light by down converting a blue emitting LED with a yellow phosphor such as Yttrium Aluminum Garnet (YAG). In another example, a multi phosphor system is used to increase the color rendering index (CRI) and can be implemented with multiple phosphors in a single layer, or by layering the phosphors individually. A multiple phosphor system based upon an ultraviolet (UV) emitting LED and a three or more phosphor system emitting a combined broad white spectrum is also feasible.

The phosphor layers should be refractive index matched to the following glass encapsulant layer, so as to not trap the light within the phosphor layer. This index matching can be achieved by using titanium dioxide, or similar nano particles, mixed in with the phosphor, similar to the index matching layer that conformally surrounds the chip [6,7]. Such index matching can also occur by directly distributing the phosphors within the glass, either in a thin layer, or distributed more broadly. Furthermore, matching the phosphor refractive index to that of the surrounding material can reduce scattering and increase quantum efficiency [8]. Such index matching of the phosphor to the encapsulant, or the phosphor matrix to the surrounding glass, is not specifically required but would increase efficiency.

The location of the phosphors for light conversion can be an important concern for efficiency and color uniformity. It is well known that phosphors decrease in efficiency with an increase in temperature, so locating them somewhat remotely from the LED should increase their efficiency. There is a balance between the distance from the LED and the ability to shape the converted light. If phosphors are placed upon the outermost surface of the glass, it would be impossible for their converted light to be optically shaped by the glass. By placing the phosphors within the glass it is possible to tune the angular CRI, along with the flux, by shaping the glass encapsulant and changing the location of the phosphor within the encapsulant. In the case of a multi-phosphor system, the order and distribution of the phosphors can be important for determining CRI and overall efficiency. Using a mixed phosphor matrix in one layer is possible, but having different color emitting phosphors at different levels can also be effective. Phosphor plates, both single and polycrystalline, can also be used. Such plates can be placed directly over the LED, or removed outside of the encapsulation as a diffusive cover.

Glass Encapsulation

Structure

High refractive index glasses are key to the extraction efficiency provided by the present invention and have been already demonstrated in various compositions [9,10].

LEDs can be encapsulated via a high refractive index glass reflow technique at elevated temperature, involving direct application of a high temperature glass to the LED.

Another reflow technique is a sol gel glass formation approach [11]. It is well known that to reach the highest refractive index, sol-gel materials must be thermally annealed at high temperatures in order to be densified. In the case that LEDs are not able to sustain high temperatures needed for direct glass application, a high refractive index glass preform can be attached to the LED, via an intermediate medium as previously described. The preforms can be molded to closely follow the contours of the chip to minimize the volume of the intermediate light extraction medium and the bonding agent. The reason for this is both the decreased thermal conductivity of the intermediate polymer medium and the possible optical degradation of the polymer. By making this volume small, even if the medium yellows and becomes optically less transparent, the absorption in the small path length can be greatly decreased as compared to current package designs that often have greater than 1 millimeter (mm) thickness of polymer.

FIG. 6 illustrates an embodiment of an encapsulated LED 600 comprising a glass 602 deposited directly on the surface, either by thermal reflow, glass/glass bonding, or another high temperature method. FIG. 6 is a schematic side view of an embodiment of the present invention in which the glass 602 is in direct contact with the LED 600, wherein the LED 600 (medium gray rectangle), the encapsulant 602 (light gray semicircular area) and the header 604 (dark grey rectangle) are shown.

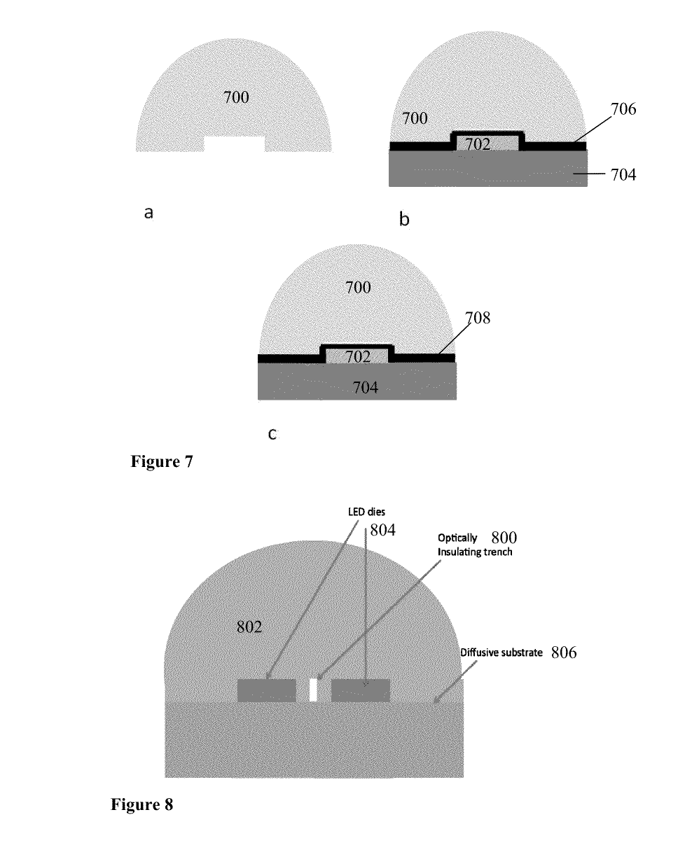

FIG. 7(a)-(c) are schematic side views of preformed glass encapsulants 700 and possible attachments to LEDs 702 on a header 704, wherein a) shows the preformed glass encapsulant 700 without refractive index grading or additional functionality, b) shows an LED 702 on a header 704 that has been bonded to a preformed glass encapsulant 700 (such as that in a)) with a non functionalized intermediate medium 706, and c) shows an LED 702 on a header 704 that has been bonded to a preformed glass encapsulant 700 such as that in a) but with a functionalized intermediate medium 708.

The shape of the glass encapsulant 700 can be very important for the extraction efficiency and also the light distribution after extraction. By using a Weierstrass sphere for the glass encapsulant, the light extracted can be maximized and distributed according to a half angle beam width of the critical angle as defined above [12]. Varying structures for the glass encapsulant can also be used, such as hemispheres and truncated ellipsoids, which can provide different radiant flux patterns with varying extraction efficiencies. By using a design such as a truncated ellipsoid, and placing the LED at the center of the ellipsoid, a collimated beam can be created, but the extraction efficiency would be decreased as compared to a Weierstrass sphere, due to extraction losses in the backside of the optic. A two part stepped index lens, that functions similar to a Weierstrass sphere for solid state lighting applications, is already reported in the literature [13].

In addition to altering the direction of the flux, the package shape may affect the uniformity of the distribution over the illuminated area. The directionality and uniformity of the emitted flux can be tuned by altering the shape of the glass encapsulant, along with altering the position of the LED die within the encapsulant, or altering the relative locations of the LED die and the phosphor (when a phosphor is used).

Structure For Multi LED Encapsulation

Up to this point, the present invention has discussed single LED encapsulation, however the above discussion can be extended to multiple LED devices for higher light output applications. In the case of multiple LEDs in a package, the placement and shape of the LEDs can play a vital role in the light output and distribution.

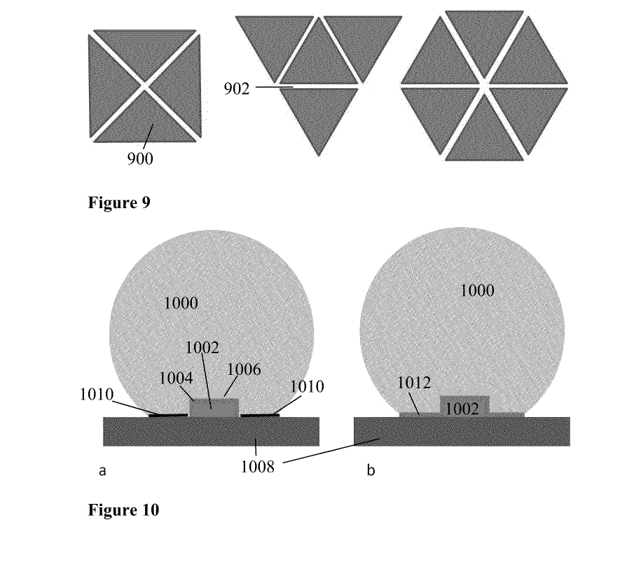

Interactions between the chips could be a concern because light emitted below or from the sidewall of one chip could easily be absorbed by a neighboring chip, decreasing the efficiency of the device. To alleviate this problem, optical “dams” can be placed between the devices. Such “dams” 800 can be achieved by trenches in the encapsulating materials 802 between the LEDs 804, which would lead to a large fraction of the incoming light undergoing TIR instead of propagating towards the neighboring LED 804, as shown in FIG. 8.

FIG. 8 illustrates an optical dam 800 of a lower index material placed between the chips 804. An optical dam can be a different material of lower index, an air gap, an optically insulating trench, or a perfect or near perfect diffuser. In FIG. 8, the LEDs 804 are formed on a diffusive substrate 806.

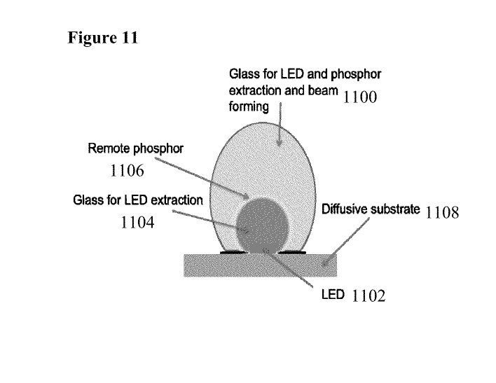

In order for point source optics to apply, it is important to place the distinct dies as closely as possible. A few possible arrangements are shown in FIG. 9. Triangles or triangular LED chips 900 have been chosen in the embodiment of FIG. 9 because they pack together efficiently into a space, but one can easily use more traditional rectangular or square chips or other shapes. The chips 900 may, or may not be, separated by optical dams 902.

Phosphor location is also an issue with such multichip systems and can be approached either by creating a more remote phosphor layer encapsulating all of the chips in the system, or by individually coating the chips in a remote fashion as described above.

Regardless of the phosphor location, it can again be useful to refractive index match the phosphor containing layer to the surrounding layers. A white light source can be obtained by multiple LED integration in the package, such as by combining direct emitting red, green, and blue LEDs. Adding a yellow LED (with the combined direct emitting red, green, and blue LEDs) may further raise the CRI and quality of the light source. A red green blue (RGB) light system can also be achieved by using a blue and red LED combined with a green phosphor, or a green and yellow phosphor.

Several such combinations of red, green, blue and yellow light sources, either direct LEDs or wavelength converted sources, can produce a white light emission out of the glass package. One could coat different LEDs in a package with different phosphors, so that if independent electrical addressing of the LEDs is used, a lamp with varying color rendering can be obtained by changing the individual LED currents.

Use of Conductive Transparent Materials

Once the premolded glass encapsulants are formed, a metal free, or an extensively metal reduced LED, can be fabricated by replacing the traditional wires, or the conformal surface contacts described above, with conductive transparent materials. This can further improve the light extraction ability of the glass encapsulants by reducing or eliminating metal absorption in the package. Such transparent conducting areas can be formed as channels within the glass by using transparent conductors such as zinc oxide (ZnO) or indium doped tin oxide (ITO). The transparent conductors can be disposed in lieu of the usual conducting contacts.

Bonding of the Glass

With both single and multichip systems, the bonding of a glass preform to the die is a challenge. There are three primary ways this can be achieved.

A first method is a direct glass to die application, requiring the die to come into direct contact with the glass. This is the highest temperature process and requires the most robust contacts capable of sustaining the temperature up to, or slightly above, the glass transition temperature of the encapsulant.

Two lower temperature processes can also be used, as shown in FIG. 10.

FIG. 10 schematically illustrates side views of a) a glass 1000 encapsulated LED 1002 with an intermediate coating 1004 and remote phosphor 1006, attached to the carrier 1008 with a secondary material 1010, and b) a glass 1000 encapsulated LED 1002 with an intermediate coating 1012 that also acts as the bonding layer, and a phosphor layer 1006.

Thus, a first method is to use the refractive index matching layer 1012 that conformally coats the top and sides of the chip 1002, along with a portion of the carrier or header 1008, to also bond the glass 1000 to chip 1002 and carrier 1008, as shown in FIG. 10b. A second approach can be to use two separate coatings, a refractive index matching layer 1004 (that matches the index of the glass 1000) on the LED 1002, and a second coating 1010 on the carrier 1008 (to act as the bond interface to the glass encapsulant 1000), as shown in FIG. 10a. In either method, the use of glass 1000 as a primary encapsulant, instead of silicones or epoxies, can help with the thermal management of the LEDs. Glasses have thermal conductivities that are about three times that of the epoxies and silicones currently used, so they provide another path for conductive cooling besides back of the chip cooling used in current devices.

Further Encapsulation

Once fully encapsulated, the LED can be further encapsulated into a traditional bulb form. To aid in the thermal management of the LEDs, the space between the external shroud and the glass encapsulated LEDs can be filled with a high thermal conductivity gas.

Although air possesses a thermal conductivity of around 0.024 W/(m K), neon can be used as a filler gas (neon has a thermal conductivity nearly twice as high, 0.046 W/(m K)). This would aid in conductive and convectively cooling the LEDs. The outer shroud, which acts primarily as a gas encapsulant, can also be used as a diffuser, or a location for the extremely remote placement of phosphors for light conversion.

Other Material System Light Emitting Devices

The present invention, as discussed above, applies to devices fabricated from III-nitrides or Group III-nitrides, but with small modifications, can easily be extended to other materials systems, such as AlInGaP and AlGaAs. The contact geometries and encapsulation concepts remain the same. The refractive indices of the relative levels/layers would change. Since the refractive index of AlInGaP and AlGaAs is n˜3.5, the index matching layer would need to have a much higher index (for example, by using GaP particles, instead of titanium dioxide, the index of the intermediate layer can be significantly increased). Correspondingly, the index of the glass encapsulant would also need to be increased in order to achieve the necessary refractive index matching. Some chip shaping, that results in high extraction from AlInGaP LEDs, is already in use in industry; as a result, such devices may not require a high index matching and can just be directly placed into the glass preform with the same intermediate layer as the InGaN devices (e.g. including a red LED within the package, for RGB or red-blue (RB) LED plus green phosphor embodiments, or white light source embodiments).

White Light Sources From LEDs, Without Phosphors

White light can be achieved via the inclusion of a red, green and blue LED into a singular package. In order to achieve this, a higher index glass would need to be used, and the matching intermediate medium would be adjusted to more closely match the needs of the red LEDs, as the red LEDs are of a higher refractive index material. Just as in the single color, or single color plus phosphor multichip packages, care would need to be taken to ensure that the light from each LED is not reabsorbed by neighboring dies.

Beam Shaping Glass

In order to extract both LED light, and phosphor downconverted light, one can use a glass structure 1100 surrounding the LED 1102, its glass encapsulant 1104, and the phosphor structure 1106 (see FIG. 11). Also shown is a diffusive substrate 1108. The glass 1100 can be used for extraction of light from the LED 1102 and remote phosphor 1106, and the glass 1104 can be for extraction of light from the LED 1102.

The shapes and placement of the various elements allow optimization for extraction efficiency, beam directionality, and angular distribution of color, in particular minimizing changes in color (CRI) with angle.

### EXAMPLE

The preferred method is a deposition of the conformal metal contacts 202 over a sidewall 212 that has previously been coated by a low optical loss dielectric 204. For high temperature encapsulation of LEDs, a refractory metal, such as tungsten, is preferable for the conformal metal contacts 202, to prevent damage to the contacts 202 during encapsulation with glass. Ideally, full glass encapsulation can be achieved on a header, with the glass being deposited in a fashion similar to that of current epoxy and silicone encapsulants (e.g., by injection molding, frit reflow or other molding methods). In the case where the LEDs cannot be subjected to the high temperatures of the glass, or glass functionality is not able to be achieved with direct molding, glass preforms can be created with the desired package dimensions and functionality, and bonded to the LED with an intermediate medium 508 (where the intermediate medium may be comprised of a silicone, epoxy, sol-gel glass or similar transparent material). Ideally, this intermediate medium will still possess a high index of refraction, either in its pure form or by introducing high refractive index particles into the medium, such as titanium dioxide. The glass preform is then attached to the LED and package using the intermediate medium. This may be required for certain metallizations and electrical contacts that are not suitable for high temperature encapsulation.

In both the direct glass application and preform attachment method, a low refractive index, thermally conductive, transparent medium 506 should be placed below the textured backside of the LED 500, to attach the LED 500 to a diffuse scattering carrier 504.

Process Steps

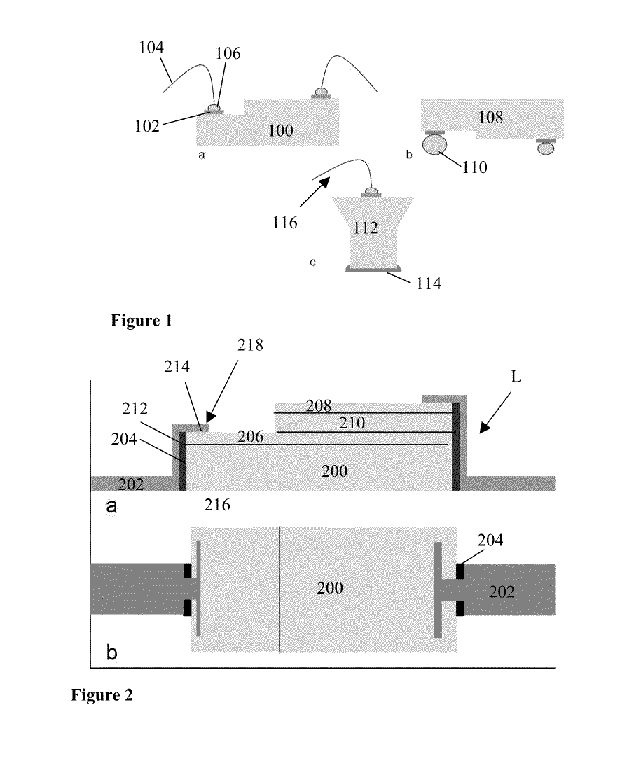

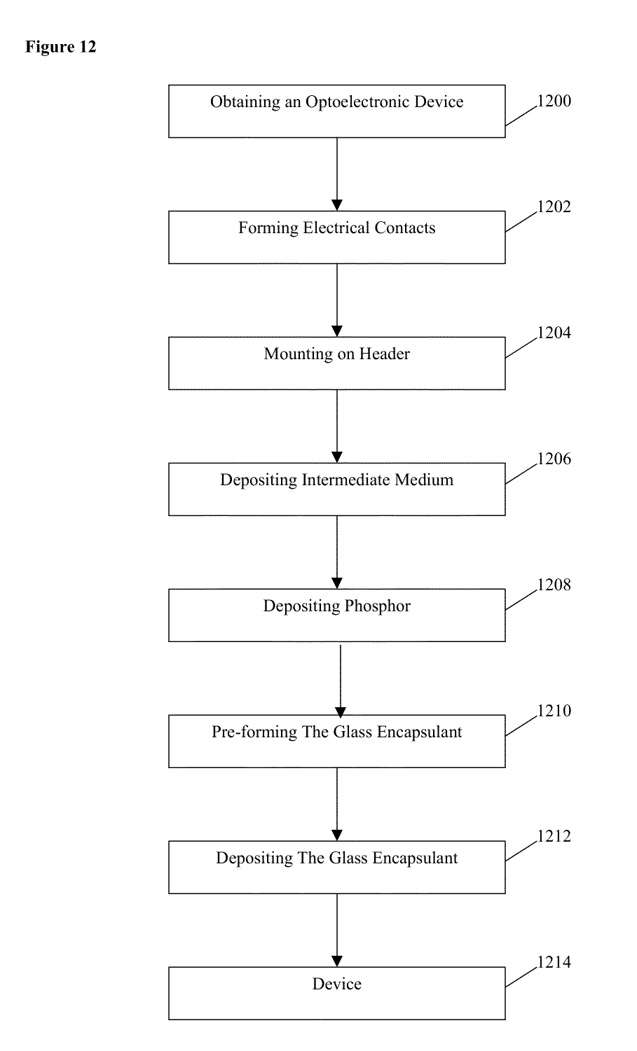

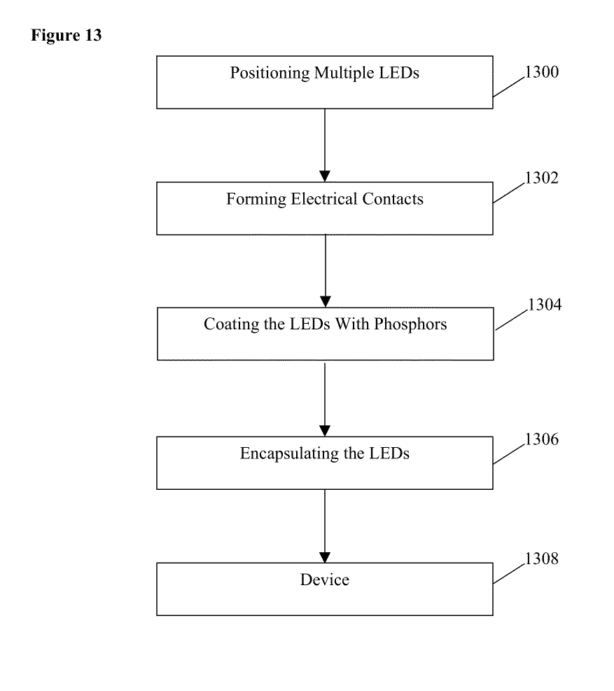

FIG. 12 illustrates a method of fabricating an optoelectronic device. The method can comprise the following steps (referring also to FIG. 1, FIG. 2, FIG. 3, FIGS. 5-7, and FIG. 11).

Block 1200 represents obtaining/providing an optoelectronic device. While in this process flow an LED is used as the example, the present invention can be applied to other optoelectronic devices, e.g., light emitting device, laser diode, solar cell).

The LED 200 can comprise an n-type layer/region 206, a p-type layer/region 208, and a light emitting active region/layer 210 between the p-type layer 208 and the n-type layer 206. The LED layers 206-210 can comprise III-nitride layers (e.g., gallium nitride, indium gallium nitride, aluminum gallium nitride), for example.

Block 1202 represents forming one or more electrical contacts to the device. The contacts can comprise conformal metal surface electrical contacts 202 conforming to, or conformal with, one or more surfaces (e.g., sidewalls 212 and top surface 214) of the device 200. The conformal surface electrical contacts 202 can include a flat surface contact 304 on a backside of the LED 300. The conformal metal surface electrical contacts 202 can include side contacts with insulator 204 between the side contacts and LED's 200 sidewalls 212 to prevent electrical shorting of the LED 200 along the sidewalls 212.

The contacts 202 can be fabricated/defined/patterned by lithography (e.g., photolithograpy). For example, the contacts 202 may be formed by depositing and exposing photoresist on the LED, etching the exposed photoresist followed by metal or transparent conductive oxide, such as Zinc Oxide, Indium Tin Oxide (ITO) deposition, and lift off of the remaining photoresist and the metal deposited onto it.

The contacts 202 can electrically contact/connect an n-type layer 206 (or p-type layer 208) of the LED 200 to the header 216, 604 or carrier 1008.

The conformal contact 202 can have the shape of, or follow the contours of, the LED chip 200, and the LED 200 shape can determine or form the shape of the contact 202. For example, the contact 202 can be in physical contact with, or attached to, the LED 200 along an entire distance L between a contact location 218 (with the n-type/p-type layer 206, 208) and the header 604, 216. The contacts 202 can be attached to the LED 200 such that the contacts 202 follow or track the shape of LED's 200 top surface 214 and sidewalls 212. The contacts can be attached at two or more points, or along substantially an entire length L, between header 604, 218 and the n-type/p-type layer 206/208.

The conformal contacts 202 can be supported by the LED 200 such that the contacts 202 are less fragile/less prone to breaking than wire bonds 104. In one example, traditional wire bonds 104 and/or bond pads 102 are not used (e.g., the conformal surface electrical contacts 202 are used instead of traditional wire bonds 104 and/or bond pads 102).

The conformal contact 202 can minimize the length L of the electrical connection between the LED 200 and the header 604.

Alternatively, the LED can be electrically contacted with backside solder bump bonds.

Block 1204 represents depositing or mounting the LED 600 on a header 604 or carrier. The conformal contacts 202 can be electrically connected to the n-type layer/p-type layer 206/208 and electrical connections on the header/carrier 604/1008 by brazing.

Block 1206 represents depositing a high refractive index intermediate medium 508, 706, 708, 1004, 1012 onto the LED 500, 702, 1002 and onto/on top of the conformal surface electrical contacts 202. The high refractive index intermediate medium 508, 706, 708, 1004, 1012 can have a refractive index between 1.8 and 2.2.

Block 1208 represents forming a phosphor layer 510, 1006, on the LED 500, 1002.

Block 1210 represents pre-forming or pre-molding glass into a modular glass preform 700 , pre-mold or premolded glass encapsulant. The glass 1104 can be shaped to perform beam shaping of light extracted from the LED, or lensing.

Block 1212 represents at least partially or totally encapsulating the device 200, 1002, 702 and the conformal surface electrical contacts 202 with a high refractive index glass 700, 602, 1000, wherein the glass 700, 602, 1000 is a primary encapsulant for the device 200, 600, 702, 1002. The high refractive index glass can be an encapsulant dome or have a dome shape or dome cross-section.

The glass 700, 602, 1000 can have a refractive index of at least 1.7, for example.

FIG. 7b illustrates an embodiment of a device where a molded glass cap 700 is placed or on top of, or attached to, the LED 702. FIG. 6 and FIG. 7a illustrate the preformed glass cap 700, 602, and FIG. 7c illustrates the cap 700 attached with a functionalized intermediate medium 708.

The glass can be deposited on the LED 600 at a temperature of more than 200 degrees or above the glass transition temperature, or at a temperature such that the glass is soft, flows, or moldable when the glass is deposited on the LED, thereby encapsulating the LED 600 with an encapsulant formed from the glass 602, and wherein the conformal surface electrical contacts 202 and the LED 600, 200 are not degraded by the deposition of the glass.

The glass 700, 602, 1000 can be deposited onto the high refractive index intermediate medium 508, 706, 708, 1004, 1012 to encapsulate the LED 500, 702, 1002, wherein the high refractive index intermediate medium 706, 708, 1004, 1012 lies or is between the LED 500, 702, 1002 and the glass 700, 602, 1000 and refractive index matches the glass 700, 602, 1000. The high refractive index intermediate medium 508, 706, 708, 1004, 1012 can index match the LED 1002, 702 and the glass 1000, 700. The high refractive index intermediate medium 508, 706, 708, 1004, 1012 can make conformal contact with, or conformally contact the LED 500, 702, 1002 and/or the glass 700, 1000.

The glass 602, 700 can be molded or formed onto the LED 600, 702 to conform to the LED 600,702, prior to, or after deposition of the glass 602, 700 on the LED 600, 702.

The glass 602 can be in direct contact with the LED 600.

A volume of non-glass and non-LED material between the LED 600, 702, 1002, and the glass 602, 700, 1000 can be minimized (e.g., less than 1 mm thickness of polymer 508 can be used).

The step can comprise applying bonding agent to the LED, wherein the device 600 comprises the bonding agent applied to the LED for attaching the LED 600 to the glass 602 and the carrier or header 604 for the LED 602. However, in one example, the high refractive index intermediate medium 508, 706, 708, 1004, 1012 can be a bonding agent that bonds the LED to the glass 700, 1000 and a carrier 1008 or header 704 for the LED 702, 1002, wherein the LED 702, 1002 is totally encapsulated by the carrier 1008 or header 704 and the glass 700, 1000.

In one example, the glass 602, 700, 1000 can replace silicone and epoxy as an encapsulant for the LED 600, 702, 1002, and there is no silicone and no epoxy encapsulant contacting the LED 600, 702, 1002. The glass 602, 700, 1000 can be positioned relative to the LED 600, 702, 1002 such that, if silicone or epoxy were used instead of the glass, the silicone or epoxy would be degraded by operation of the LED 600, 702, 1002.

Further or additional encapsulants can also be used/provided. FIG. 11 is a schematic side view of a glass structure 1100 surrounding the LED 1102, its glass encapsulant 1104, and the phosphor structure 1106.

Block 1214 represents the end result of the above steps, an optoelectronic device comprising, e.g., an LED 200, 600, 702 1002 including one or more conformal surface electrical contacts 202 conforming to surfaces 212, 214 of the device 202; and a high refractive index glass 602, 700, 1000 partially or totally encapsulating the device 200, 600, 702 1002 and the conformal surface electrical contacts 202, wherein the glass 602, 700, 1000 is a primary encapsulant for the device 200, 600, 702, 1002. The glass can be formed (or shaped to perform beam shaping) prior to or after attaching the glass to the LED or encapsulating the LED with the glass.

The device can further comprise header 604, 704 or carrier 1008 for the LED 600, 702, 1002, wherein the glass 602, 700, 1000 and the header 604 totally encapsulate the LED 600, 702, 1002.

At least one of the conformal surface electrical contacts 202 can extend from a top surface 214 of the LED 200 and along sidewalls 212 of the LED 200 to a header 604 or carrier 1008 supporting the LED 600, 200, wherein the header 604 and the glass 602 encapsulate the LED 600, 200.

In one example, when the glass is a premolded glass encapsulant, the LED can be electrically contacted with backside solder bump bonds.

The conformal metal surface electrical contacts 202 can be comprised of refractory metals (e.g., but not limited to, titanium, chromium, platinum, and refractory alloys, also eventually containing aluminum, nickel or gold) tolerant to temperatures greater than 200 degrees Celsius or greater than the glass' 602, 700, 1000 transition temperature.

While a phosphor layer 510, 1006 can be formed on the LED 500, 1002 such that the phosphor layer 510, 1006 is between the glass 1000 and the LED 1002, the phosphor layer can be applied at other locations.

Steps can be performed in a different order, added, omitted, as desired.

FIG. 13 illustrates a method of fabricating a light source comprising the following steps (referring also to FIG. 2, FIG. 8, and FIG. 9).

Block 1300 represents positioning multiple LEDs 900, 802. The step can comprise forming optical dams 902, 800 to separate the LEDs 802, 900. The step can comprise shaping and positioning the LEDs 900 such that the LEDs 900 act as a point source.

Block 1302 represents forming electrical contacts, e.g., one or more conformal surface electrical contacts 202 conforming to surfaces of the LEDs 200. In one example, traditional wire bonds 106 and/or bond pads 102 are not used.

Block 1304 represents coating the different LEDs with different phosphors (emitting different colors).

Block 1306 represents partially or totally encapsulating the LEDs 802 and the conformal surface electrical contacts 202 with a high refractive index glass 806. The glass 806 can be a primary encapsulant for the devices 802. The glass can be an encapsulant dome and the LEDs can be closely packed near a center of the encapsulant dome.

Block 1308 represents the end result, a device, e.g., as shown in FIG. 8. The LEDs can be in a single package. The LEDs can be independently electrically addressed so that varying color rendering is obtained by changing individual LED driving currents.

Steps can be performed in a different order, added, omitted, as desired.

Possible Modifications

A large selection of materials is available for sidewall 212 insulation purposes. Any material with a high refractive index and insulating properties can serve as a conformal sidewall coating 204.

To minimize the optical losses at the metal 202 to LED 200 interface, the dielectric 204 can be a multi-layer film designed instead to act as a reflector, forcing the light back into the chip 200, or a low index material taking advantage of the total internal reflection similar to the proposed backside medium 506. The use of a highly conductive optically transparent contact to replace the traditional metal film or as a conformal contact 202 would greatly minimize the losses and allow for nearly any dielectric 204 to be used.

Additionally, metal or dielectric mirrors (single or multilayer) can be introduced onto the chip surface in the case of n-side up conformal contacts 202.

A variety of metals, alloyed or not, can be used for the actual sidewall contacts 202, the selection of which may be influenced by the LED composition and structure, transparent contact 202 composition, or the encapsulation media.

In n-side up flip chip style structures 300 (e.g., FIG. 3), the mirror on the back surface can be extremely important and would have to be carefully fabricated to ensure low optical loss, if included at all. Optionally, the inclusion of a photonic crystal 306 on the p-side of the active region can be used to reduce the optical loss in the n-side up style structures 300, by minimizing the interaction of the emitted light with the mirror. Similarly, photonic crystals can be introduced into the sidewall dielectrics for the same purpose. The metals (e.g., in contacts 308) used in the high temperature braze, and the metals which they are contacting in the package, can be selectively chosen for high temperature tolerance, low resistance and high reflectivity.

Deposition techniques for all materials can include evaporation, sputtering, atomic layer deposition, electroplating, CVD, pulsed laser deposition, ion beam deposition.

The composition of the glass to be used for the encapsulant can be changed and tuned to adjust the coefficient of thermal expansion, the index of refraction, transparency, glass transition temperature and thermal conductivity. The attachment of the glass encapsulant, if preformed, may be attached by an organic (such as silicone or epoxy) or inorganic component (which may or may not have additives), which component can include high refractive index nano- or micro- particles to help refractive index match the attaching polymer to the glass encapsulant. Other functionality can be added, such as phosphor particles, to create a white light. Phosphors in plate form, either single or polycrystalline, may be added within or around the preform in lieu of, or in addition to, phosphor particles within the encapsulant itself.

The product(s) produced include LEDs for general and specialty lighting applications, including general lighting both indoor and outdoor, automotive lighting and other lighting applications.

One or more aspects of the present invention may be applied to other light emitting devices (e.g., lasers, laser diodes, superluminescent diodes), electronic devices (e.g., transistors), optoelectronic devices, or solar cells.

Advantages and Improvements

The glass encapsulation with a high refractive index serves to increase the extraction efficiency of LEDs significantly. Added functionality within the encapsulant, including, but not limited to, embedded phosphor particles or coatings, graded refractive indices, and physical shaping of the encapsulant, can enhance LED performance by increasing extraction efficiency. Glass encapsulants should provide for rigid, long lasting encapsulation that is resistant to yellowing and other decreases in optical transparency.

Elimination of traditional wire bonds can improve external LED efficiency by reducing the amount of light absorption in the package, and by allowing high temperature encapsulation using high refractive index glasses. Higher current operation and increased device reliability can be achieved with the removal of standard wire bonds. Two of the failure mechanisms in LEDs are wire failure or bond delamination. By using surface conformal contacts, the failure of LEDs by wire bond delamination can be prevented.

The distinct advantage is the ability to use flat refractory metal contacts, combined with high refractive index glasses to encapsulate the LEDs, thus increasing extraction efficiencies by increasing the refractive index of the encapsulant and decreasing the absorption from the metalized areas. Additionally, glass encapsulants provide additional functionality via index grading, better thermal conductivity, high transparency and resistance to degradation via UV light. The embedding of phosphor particles, and the physical shaping of the glass will allow the light output of the LEDs to be tuned specifically. Currently, wire bond and bump bond failure are the primary concerns in using higher temperature glass encapsulants, and in current devices, they act as optical absorbers. The replacement of wire bond and bump bonds with surface contacts, combined with high refractive index glass encapsulation, can lead to longer LED lifetimes at higher extraction efficiencies. The use of preforms allows for the continued use of traditional flip chip bonds, or the inclusion of sidewall contacts, while minimizing the optical path through an organic material which can optically degrade with time. Preforms will also provide more mechanical protection than current silicones. Although filled silicones and epoxies can provide high refractive indices, the yellowing of the epoxies and the mechanical softness of the silicones still puts glass preforms at an advantage.

### REFERENCES

The following references are incorporated by reference herein.
[1] R. Himmelhuber, P. Gangopadhyay, R. Norwood, D. Loy and N. Peyghambarian. Opt. Matrls. Exp. 12 (2011).
[2] N. Nakayama and T. Hayashi. J. Apl. Poly. Sci. 105 3662-3672 (2007).
[3] J. Lik Hang Chau, Y. Lin, A. Li, W. Su, K. Chang, S. Hsu, T. Li. Materials Letters 61 2908-2910 (2007).
[4] H. Su, W. Chen. J. Matrl. Chem. 18 1139-1145 (2008).
[5] Lester et al, High refractive index package material and a light emitting device encapsulated with such material, U.S. Pat. No. 5,777,433, Jul. 7, 1998.
Muller, G. O, Light emitting devices utilizing nanoparticles. European Patent EP 1369935 A1, Dec. 10, 2003.
[7] Taskar, N, Nanocomposite photonic structures for solid state lighting. U.S. Pat. No. 7,259,400 B1, Aug. 21, 2007.
[8] Allen S et al., Nearly index-matched luminescent glass-phosphor composites for photonic applications, United States patent publication US 2010/0263723 A1, Oct. 21, 2010.
[9] Nakashima, N, High refractive index glass compositions. U.S. Pat. No. 4,082,427, Apr. 4, 1978.
[10] Yono et al., Titanium containing oxide glass and method for production thereof. United States patent publication US 2010/0003514 A1, Jan. 7, 2010.
He, X.-C. Yuan, N. Q. Ngo, J. Bu, and V. Kudryashov. Optics Letters, 28 9 (2003).
[12] W. N. Carr. Infrared Physics, 6 1-19 (1966).
[13] Destain P, LED with compound encapsulant lens. U.S. Pat. No. 7,798,678 B2, Sep. 21, 2010.

Conclusion

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. An optoelectronic device, comprising:
one or more conformal surface electrical contacts conforming to surfaces of at least one light emitting device; and
a high refractive index glass, having a refractive index of at least 1.7, partially or totally encapsulating the device and the conformal surface electrical contacts, wherein the glass is a primary encapsulant for the at least one light emitting device.

2. The device of claim 1, wherein the light emitting device is a light emitting diode (LED).

3. The device of claim 2, wherein at least one of the conformal surface electrical contacts extends from a top surface of the LED and along sidewalls of the LED to a header or carrier supporting the LED, wherein the header and the glass encapsulate the LED.

4. The device of claim 2, wherein the conformal surface electrical contacts include a flat surface contact on a backside of the LED.

5. The device of claim 2, further comprising a high refractive index intermediate medium, wherein the high refractive index intermediate medium:
is on top of the conformal surface electrical contacts and between the LED and the glass,
has a refractive index equal to or greater than the glass' refractive index, and less than or equal to the LED's refractive index, and
index matches the glass.

6. The device of claim 5, wherein the high refractive index intermediate medium is a bonding agent that bonds the LED to the glass and a carrier or header for the LED, wherein the LED is totally encapsulated by the carrier and the glass.

7. The device of claim 2, wherein the conformal metal surface electrical contacts include side contacts with insulator between the side contacts and LED's sidewalls to prevent electrical shorting of the LED along the sidewalls.

8. The device of claim 2, further comprising a phosphor layer between the glass and the LED.

9. The device of claim 2, wherein a volume of non-glass and non-LED material between the LED and the glass is minimized.

10. The device of claim 2, wherein the glass is in direct contact with the LED.

11. The device of claim 2, wherein the glass is molded or formed onto the LED to conform to the LED's shape.

12. The device of claim 2, wherein:
the glass replaces silicone and epoxy as an encapsulant for the LED, and there is no silicone and no epoxy encapsulant contacting the LED.

13. The device of claim 1, wherein the conformal surface electrical contacts are used instead of traditional wire bonds and/or bond pads.

14. The device of claim 1, wherein the conformal metal surface electrical contacts are comprised of refractory metals tolerant to temperatures greater than 200 degrees Celsius or greater than the glass' transition temperature.

15. The device of claim 1, comprising:
a plurality of at least one light emitting device comprising multiple Light Emitting Diodes (LEDs) with the one or more conformal surface electrical contacts conforming to surfaces of the LEDs; and
the high refractive index glass partially or totally encapsulating the LEDs and the conformal surface electrical contacts, wherein traditional wire bonds and bond pads are not used.

16. The device of claim 15, wherein optical dams separate the LEDs.

17. The device of claim 15, wherein the LEDs are shaped and positioned such that the LEDs act as a point source.

18. The device of claim 15, wherein the glass is an encapsulant dome and the LEDs are closely packed near a center of the encapsulant dome.

19. The device of claim 15, wherein:
the LEDs are in a single package,
different LEDs are coated with different phosphors, and
the LEDs are independently electrically addressed so that varying color rendering is obtained by changing individual LED currents.

20. A method of fabricating an optoelectronic device, comprising:
forming one or more conformal surface electrical contacts conforming to surfaces of a Light Emitting Diode (LED); and
at least partially or totally encapsulating the device and the conformal surface electrical contacts with a high refractive index glass, wherein the glass is a primary encapsulant for the device.

21. The method of claim 20, wherein the glass is deposited on the LED at a temperature of more than 200 degrees or above the glass transition temperature, or at a temperature such that the glass is soft, flows, or moldable when the glass is deposited on the LED, thereby encapsulating the LED, and the conformal surface electrical contacts and the LED are not degraded by the deposition of the glass.

22. The method of claim 20, wherein the LED is deposited or mounted on a header prior to encapsulation.

23. The method of claim 20, further comprising:
depositing a high refractive index intermediate medium onto the LED and the conformal surface electrical contacts; and
depositing the glass onto the high refractive index intermediate medium to encapsulate the LED, wherein the high refractive index intermediate medium is between the LED and the glass and refractive index matches the glass.

24. The method of claim 23, further comprising pre-forming or pre-molding the glass into a modular glass preform, prior to encapsulating the LED with the glass.
